(19) United States
(12) Patent Application Publication
(10) Pub. No.: US 2011/0007483 A1
(43) Pub. Date: Jan. 13, 2011

(54) ELECTRONIC DEVICE AND SATA EXTENSION BOARD THEREOF

(75) Inventors: CHENG-YANG LI, Shenzhen City (CN); YI RUI, Shenzhen City (CN); JIAN-SHE SHEN, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/533,010

(22) Filed: Jul. 31, 2009

(30) Foreign Application Priority Data
Jul. 7, 2009 (CN) 200910304089.X

(51) Int. Cl. H05K 5/00; H01R 12/00

(52) U.S. Cl. 361/752; 439/55

(57) ABSTRACT

An electronic device includes a chassis used to accommodate a serial advanced technology attachment (SATA) extension board. The SATA extension board includes a main body and a fixing element mounted on the main body to engage with an extended port of the chassis. The main body includes a signal interface, a power interface, a SATA signal connector connected to the signal interface, and a SATA power connector connected to the power interface. The SATA signal connector and the SATA power connector passes through the fixing element to expose out of the chassis. The SATA extension board only needs to be installed into the chassis once, the electronic device without external SATA interface originally can be connected and disconnected to the SATA device from outside the chassis many times, without having to disassemble and assemble the chassis each time.

### BACKGROUND

1. Technical Field

The present disclosure relates to electronic devices, and in particular, to an electronic device with a serial advanced technology attachment (SATA) extension board.

2. Description of Related Art

A SATA interface based on industry standards is a primary internal serial interface of computer systems. The SATA interface connects the computer systems to SATA devices, such as SATA hard disk drives, with fast and efficient data transfer, full duplex, and hot swapping. However, the SATA interface is generally mounted on a motherboard received in a chassis of a computer system, which means that when a SATA device is added to the computer system, the chassis needs to be disassembled firstly, then the SATA device installed, and the chassis reassembled, which is time consuming and complicated.

### BRIEF DESCRIPTION OF THE DRAWINGS

FIG. 1 is an isometric, assembled, partial view of an embodiment of an electronic device, the electronic device including a serial advanced technology attachment (SATA) extension board.

FIG. 2 is an enlarged, isometric view of the SATA extension board of FIG. 1.

FIG. 3 is a block diagram of an embodiment of a SATA device connected to the electronic device of FIG. 1.

### DETAILED DESCRIPTION

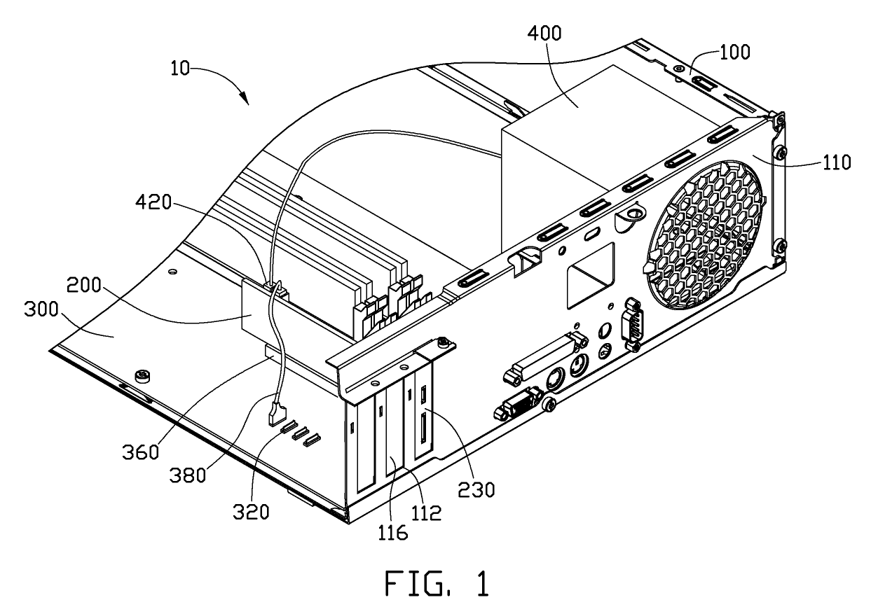

Referring to FIG. 1, an exemplary embodiment of an electronic device 10 includes a chassis 100 and a serial advanced technology attachment (SATA) extension board 200 accommodated in the chassis 100.

A printed circuit board (PCB) 300 and a power supply device 400 are received in the chassis 100. The chassis 100 includes a back panel 110 defining a plurality of extension slots 112. The PCB 300 includes a plurality of SATA interfaces 320 and a plurality of expansion sockets 360, such as peripheral component interconnect expansion sockets. The power supply device 400 supplying power for the electronic device 10 includes a power connector 420. In one embodiment, the electronic device 10 may be a computer, the PCB 300 may be a motherboard of the computer, and the power supply device 400 may be a computer power supply device, such as an advanced technology extended power supply. A removable shielding sheet 116 is covered on each of idle extension slots 112 of the plurality of extension slots 112, to prevent electromagnetic waves from getting through the idle extension slots 112. When one of the idle extension slots 112 is to be used, the shielding sheet 116 can be easily removed from the extension slot 112.

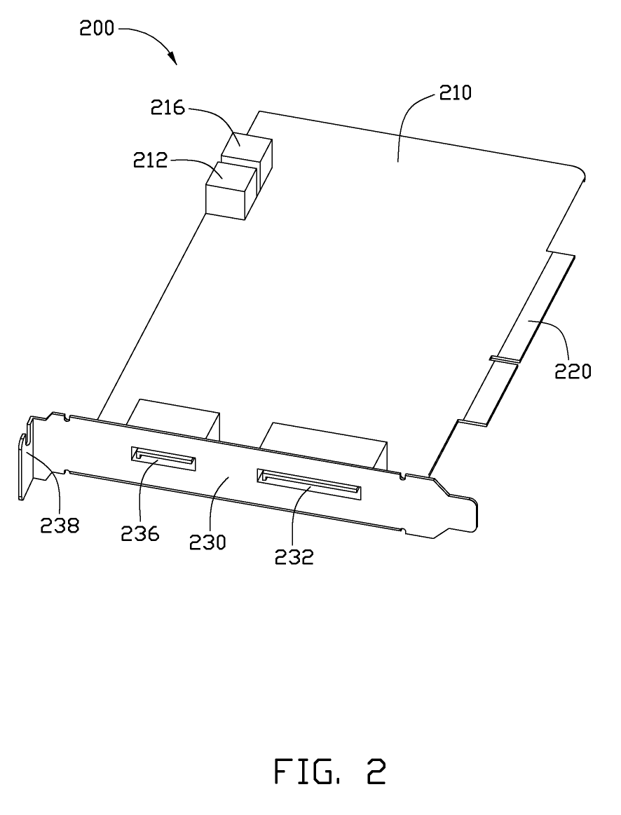

Referring to FIG. 2, the SATA extension board 200 is used to connect to a SATA device, such as a SATA hard disk drive. The SATA extension board 200 includes a main body 210 and a joint portion 220 extending horizontally from a first side of the main body 210. A fixing element 230 is mounted to a first end of the main body 210, with a SATA signal connector 232 and a SATA power connector 236 being exposed therethrough. A signal interface 212 electrically connected to the SATA signal connector 232 and a power interface 216 electrically connected to the SATA power connector 236 are mounted to a second side opposite to the first side of the main body 210, adjacent to a second end opposite to the first end of the main body 210. The fixing element 230 includes a fixing portion 238 perpendicularly extending from a first end of the fixing element 230. In one embodiment, the joint portion 220 may be engaged in any one of the plurality of expansion sockets 360, a shape of the fixing element 230 may match a shape of any one of the extension slots 112, therefore, the fixing element 230 may be interferentially received in one of the extension slots 112, to replace the corresponding shielding sheet 116.

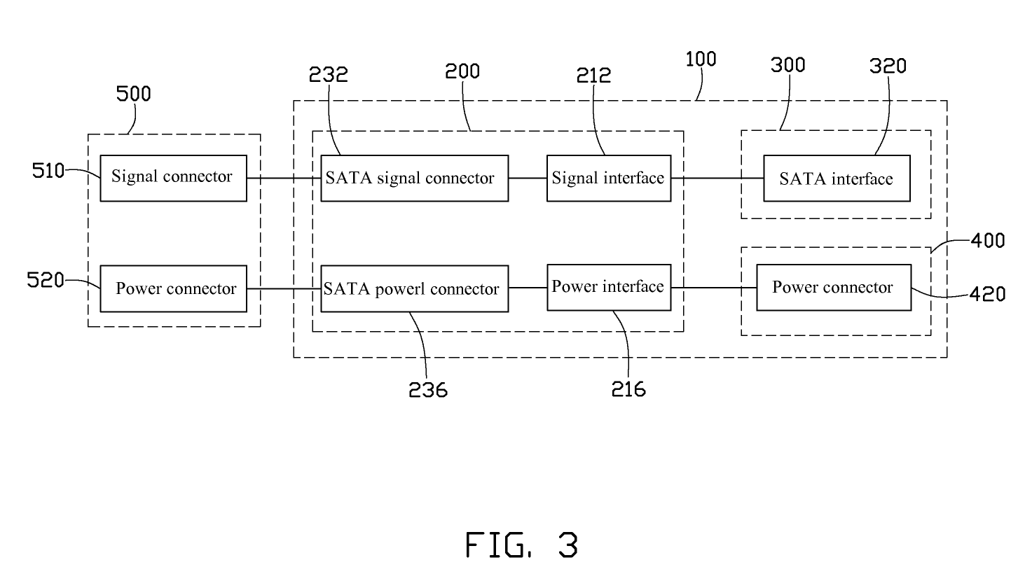

Referring to FIG. 3, when a SATA device 500 including a signal connector 510 and a power connector 520 is connected to the electronic device 10 from an outer side of the electronic device 10 and without directly using external SATA interfaces, the chassis 100 is opened to receive the SATA extension board 200. The joint portion 220 is inserted into one of the expansion sockets 360. The shielding sheet 116 of the corresponding extension slot 112 is taken away, to enable the fixing element 230 to be interferentially received in and cover the extension slot 112, and the fixing portion 238 being fixed to the back panel 110. The signal interface 212 is connected to one of the plurality of SATA interfaces 320 via a cable 380, and the power interface 216 is connected to the power connector 420. The chassis 100 is then assembled, the SATA signal connector 232 and the SATA power connector 236 are exposed out of the chassis 100 through the fixing element 230, and the SATA device 500 can connect to the SATA signal connector 232 and the SATA power connector 236 outside the chassis 100. In one embodiment, the cable 380 includes two cable connectors fixed to opposite ends of the cable 380 respectively, one cable connector is connected to the signal interface 212, and the other cable connector is connected to the SATA interface 320.

When the SATA device 500 is connected to the electronic device 10 with the SATA extension board 200 during the electronic device 10 working normally, the signal connector 510 is connected to the SATA signal connector 232, and the power connector 520 is connected to the SATA power connector 236. The power supply device 400 supplies power to the SATA device 500 via the power connector 420, the SATA extension board 200, and the power connector 520. The SATA device 500 communicates with the printed circuit board 300 via the signal connector 510, the SATA extension board 200, the cable 380, and the SATA interface 320.

As described above, the SATA extension board 200 only needs to be installed into the chassis 100 once, the electronic device 10 without external SATA interface originally can be connected and disconnected to the SATA device 500 from outside the chassis 100 many times, without having to disassemble and assemble the chassis 100 each time.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1 An electronic device, comprising:
a chassis defining an extension slot;
a printed circuit board accommodated in the chassis and comprising a serial advanced technology attachment (SATA) interface;
a power supply device accommodated in the chassis, the power supply device comprising a power connector; and
a SATA extension board accommodated in the chassis and comprising:
a main body comprising a signal interface electrically connected to the SATA interface, a power interface electrically connected to the power connector, a SATA signal connector electrically connected to the signal interface, and a SATA power connector electrically connected to the power interface; and
a fixing element mounted to the main body, with the SATA signal connector and the SATA power connector passing through the fixing element, wherein the fixing element covers the extension slot;
wherein the SATA signal connector and the SATA power connector are exposed out of the chassis through the fixing element.

2. The electronic device of claim 1, wherein the printed circuit board further comprises an expansion socket, the SATA extension board further comprises a joint portion extending from the main body to engage with the expansion socket.

3. The electronic device of claim 1, wherein the chassis further comprises a shielding sheet to cover the expansion slot in response to the SATA extension board being not accommodated in the chassis.

4. The electronic device of claim 1, wherein the fixing element comprises a fixing portion fixed to the chassis.

5. A serial advanced technology attachment (SATA) extension board, comprising:
a main body comprising a signal interface, a power interface, a SATA signal connector electrically connected to the signal interface, and a SATA power connector electrically connected to the power interface; and
a fixing element mounted to the main body, wherein the SATA signal connector and the SATA power connector are mounted to and passed through the fixing element.

6. The SATA extension board of claim 5, further comprising a joint portion extending from the main body to engage with an expansion socket of a printed circuit board.
